(19) United States
(12) Patent Application Publication
(10) Pub. No.: US 2024/0203916 A1
(43) Pub. Date: Jun. 20, 2024

(54) METHOD OF MANUFACTURING SEMICONDUCTOR STRUCTURE HAVING BONDING ELEMENT

(71) Applicant: NANYA TECHNOLOGY CORPORATION, New Taipei City (TW)

(72) Inventor: WU-DER YANG, TAOYUAN CITY (TW)

(21) Appl. No.: 18/379,837

(22) Filed: Oct. 13, 2023

Related U.S. Application Data
(62) Division of application No. 18/081,856, filed on Dec. 15, 2022.

(51) Int. Cl. H01L 23/00; H01L 23/31; H01L 23/373; H01L 23/48; H01L 23/498

(52) U.S. Cl. CPC H01L 24/05; H01L 23/3128; H01L 23/3735; H01L 23/481; H01L 23/49816; H01L 24/16; H01L 2224/16257; H01L 2924/01029; H01L 2924/15311

(57) ABSTRACT

A method of manufacturing a semiconductor structure and a semiconductor structure is provided. The manufacturing method for the semiconductor structure includes the steps of providing a substrate, wherein the substrate includes a conductive pattern, forming a bonding pad directly on the conductive pattern, and bonding a chip to the substrate through the bonding pad.

### CROSS-REFERENCE TO RELATED APPLICATION

This application is a divisional application of U.S. Non-Provisional application Ser. No. 18/081,856 filed Dec. 15, 2022, which is incorporated herein by reference in its entirety.

### TECHNICAL FIELD

The present disclosure relates to a semiconductor structure and a method of manufacturing the same, and more particularly, to a semiconductor structure having one or more bonding elements, and a method of manufacturing the same.

### DISCUSSION OF THE BACKGROUND

Semiconductor devices are essential for many modern applications. With the advancement of electronic technology, semiconductor devices are becoming smaller in size while having greater functionality, greater amounts of integrated circuitry, and enhanced processing speeds. Therefore, there is a continuous need to improve the manufacturing process of semiconductor devices and address the above complexities.

This Discussion of the Background section is provided for background information only. The statements in this Discussion of the

Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor structure. The semiconductor structure includes a substrate having a conductive pattern. The semiconductor structure may also include a chip. The semiconductor structure may furthermore include a bonding pad connecting the substrate to the chip, where the bonding pad directly contacts the conductive pattern of the substrate.

Another aspect of the present disclosure provides a semiconductor structure. The semiconductor structure includes a substrate having a conductive pattern. The semiconductor structure may also include a chip having a conductive pad. The semiconductor structure may furthermore include a solder-free bonding structure bonding the conductive pattern of the substrate to the conductive pad of the chip.

Another aspect of the present disclosure provides a method of manufacturing a semiconductor structure. The method may include providing a substrate, the substrate having a conductive pattern. The method may also include forming a bonding pad directly on the conductive pattern. The method may furthermore include bonding a chip to the substrate through the bonding pad.

In the semiconductor structure, with the design of one or more bonding pads directly contacting one or more conductive patterns of a substrate to connect the substrate to a chip, additional semiconductor processes of forming conductive pillars on the chip can be omitted, and thus the costs as well as the cycle time can be reduced. In addition, with the design of the bonding pad being a plated metal layer, the cost of a plating process is relatively low, and the bonding pad formed by the plating process can be provided with a relatively small thickness. Therefore, the transmission distance (or the transmission path) provided by the bonding pad is significantly shortened, which is advantageous to high speed transmission.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

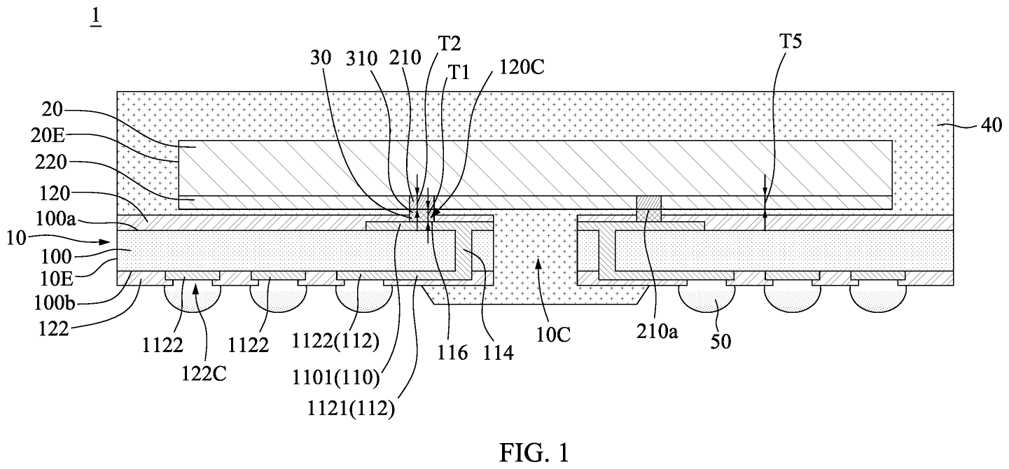

FIG. 1 is a cross-sectional view of a semiconductor structure, in accordance with some embodiments of the present disclosure.

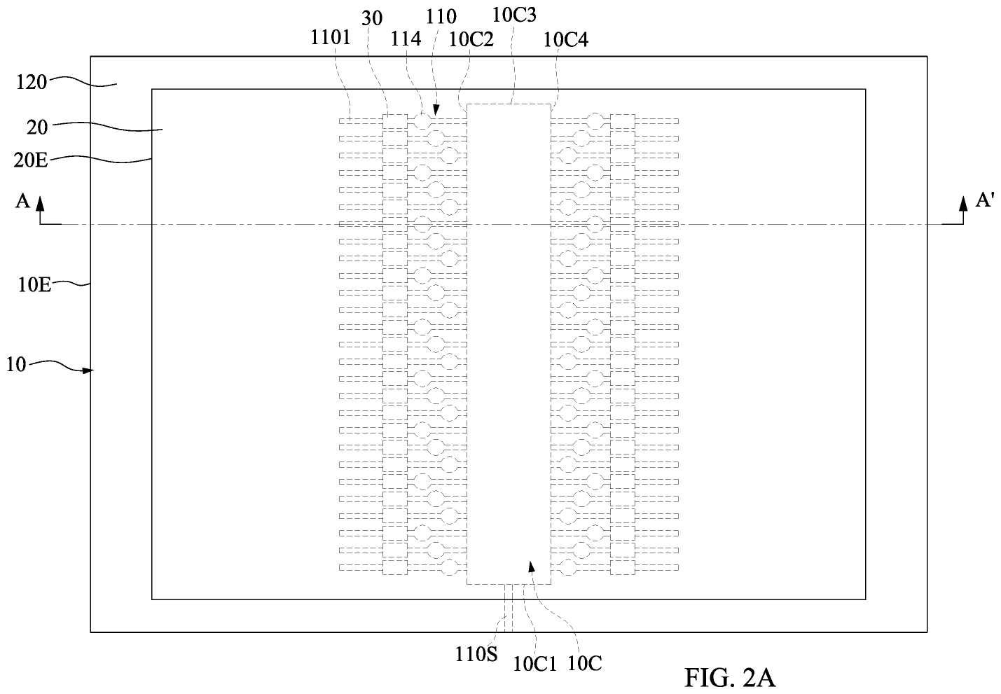

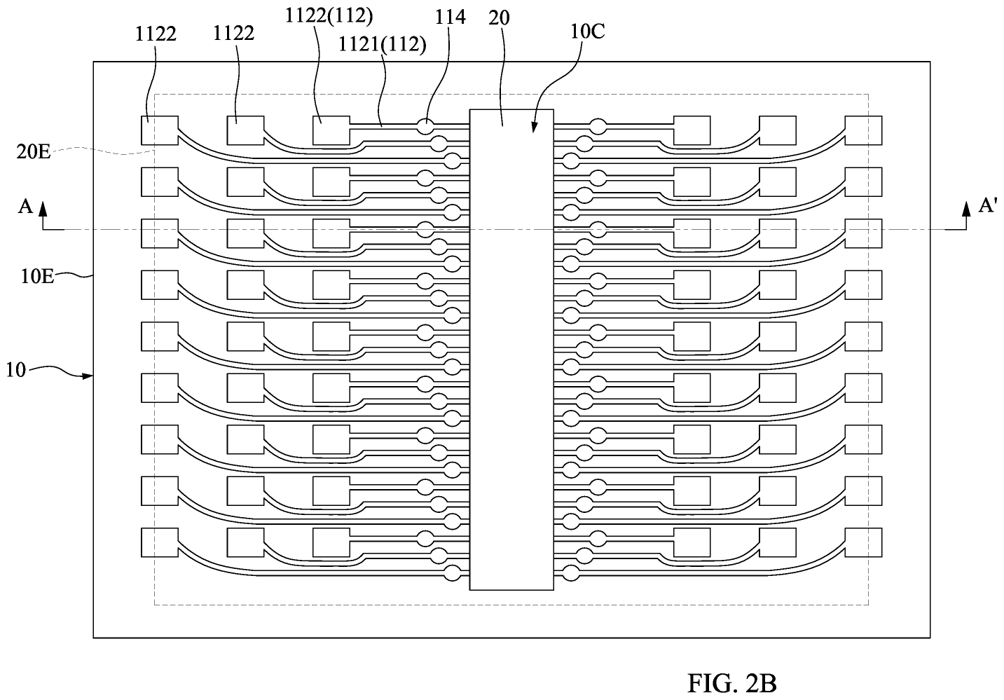

FIG. 2A is a view showing one side of a semiconductor structure, in accordance with some embodiments of the present disclosure.

FIG. 2B is a view showing another side of a semiconductor structure, in accordance with some embodiments of the present disclosure.

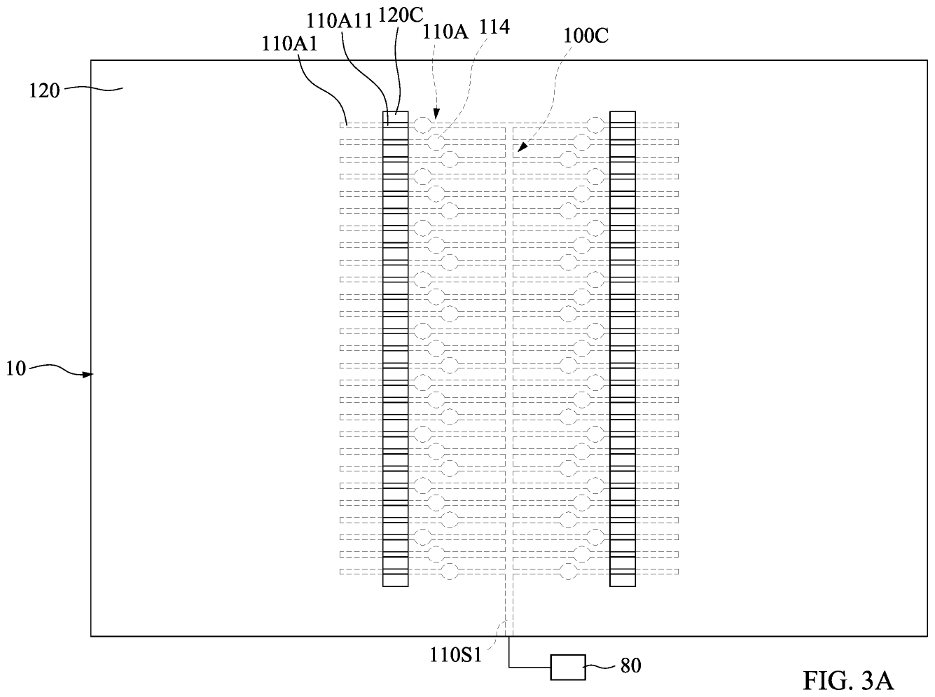

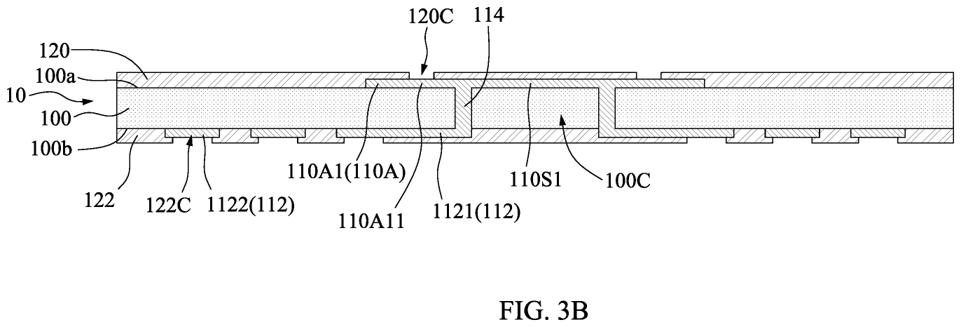

FIG. 3A illustrates one or more stages of a method of manufacturing a semiconductor structure, in accordance with some embodiments of the present disclosure.

FIG. 3B illustrates one or more stages of a method of manufacturing a semiconductor structure, in accordance with some embodiments of the present disclosure.

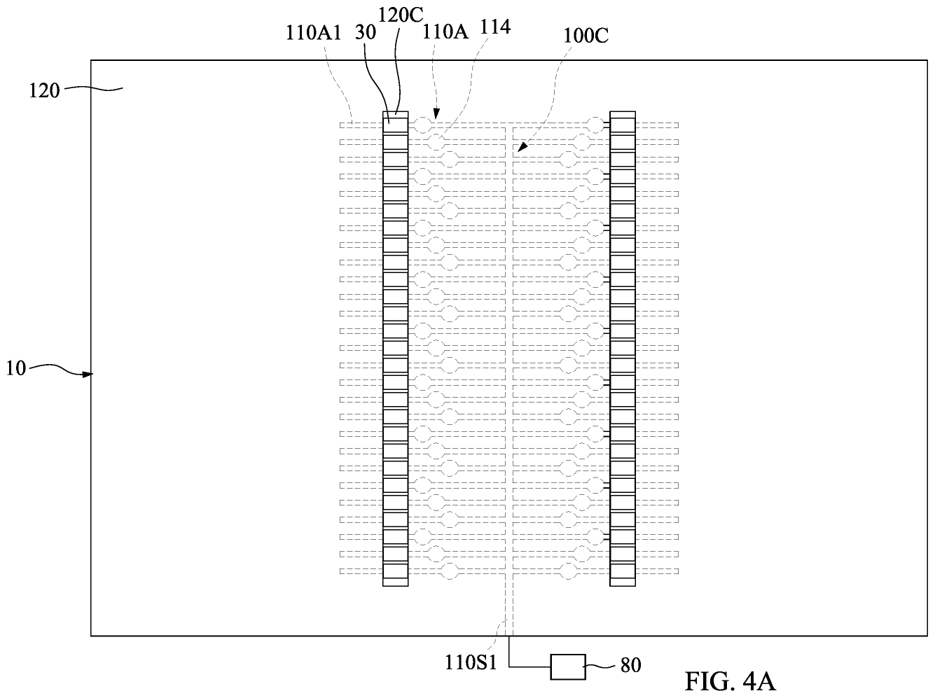

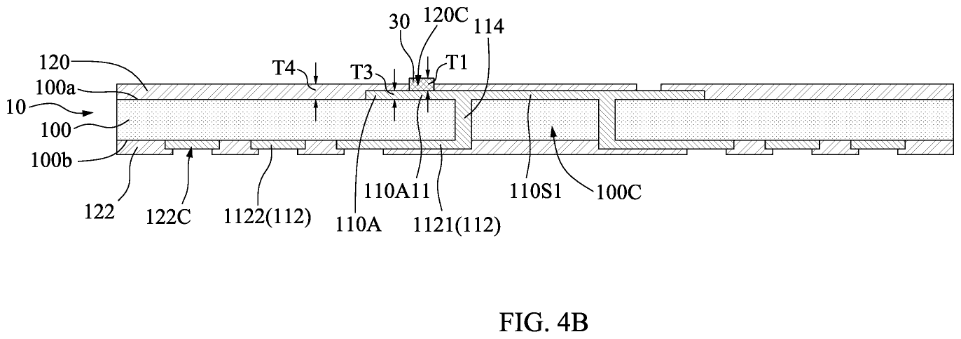

FIG. 4A illustrates one or more stages of a method of manufacturing a semiconductor structure, in accordance with some embodiments of the present disclosure.

FIG. 4B illustrates one or more stages of a method of manufacturing a semiconductor structure, in accordance with some embodiments of the present disclosure.

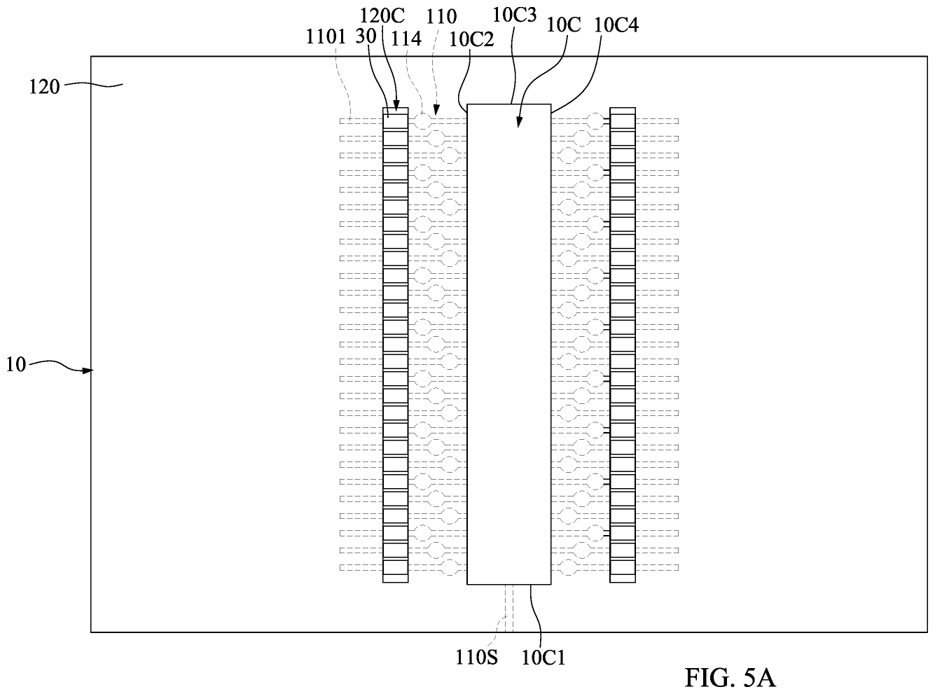

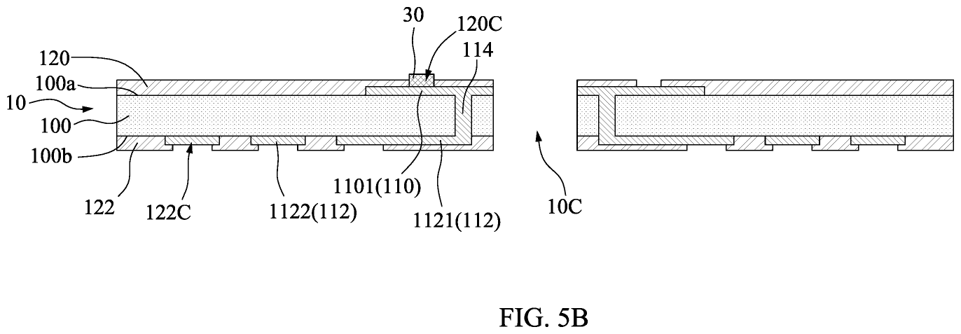

FIG. 5A illustrates one or more stages of a method of manufacturing a semiconductor structure, in accordance with some embodiments of the present disclosure.

FIG. 5B illustrates one or more stages of a method of manufacturing a semiconductor structure, in accordance with some embodiments of the present disclosure.

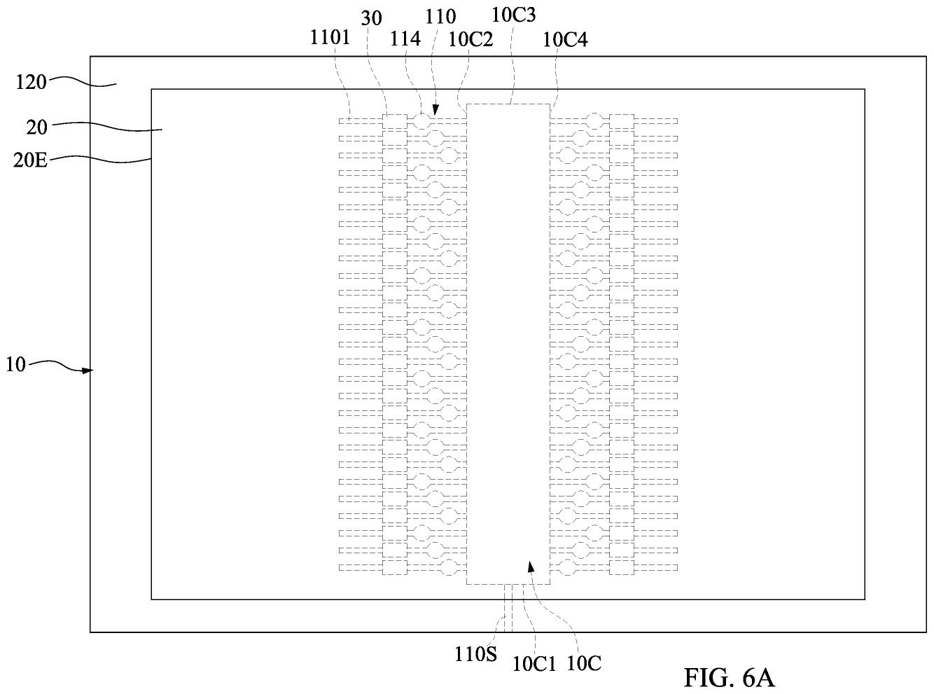

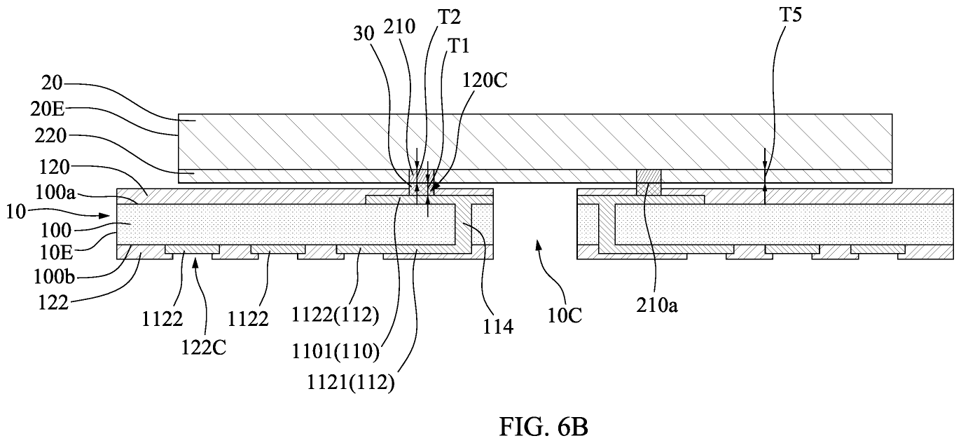

FIG. 6A illustrates one or more stages of a method of manufacturing a semiconductor structure, in accordance with some embodiments of the present disclosure.

FIG. 6B illustrates one or more stages of a method of manufacturing a semiconductor structure, in accordance with some embodiments of the present disclosure.

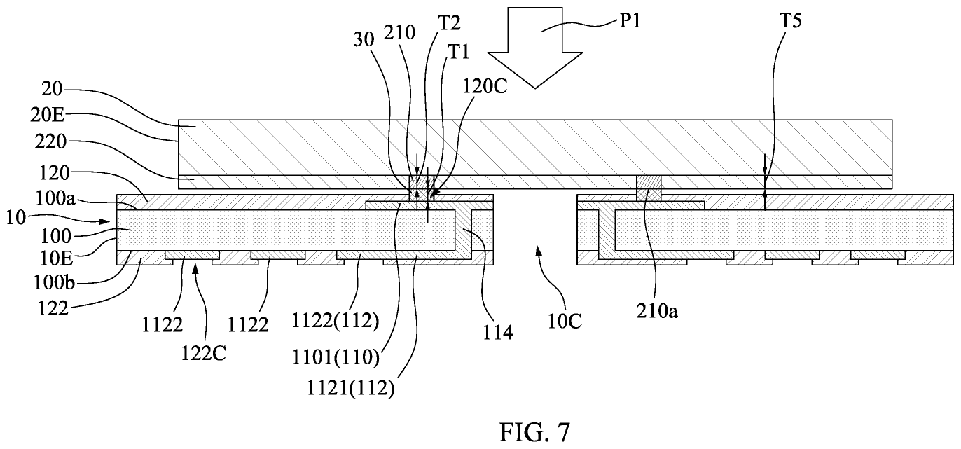

FIG. 7 illustrates one or more stages of a method of manufacturing a semiconductor structure, in accordance with some embodiments of the present disclosure.

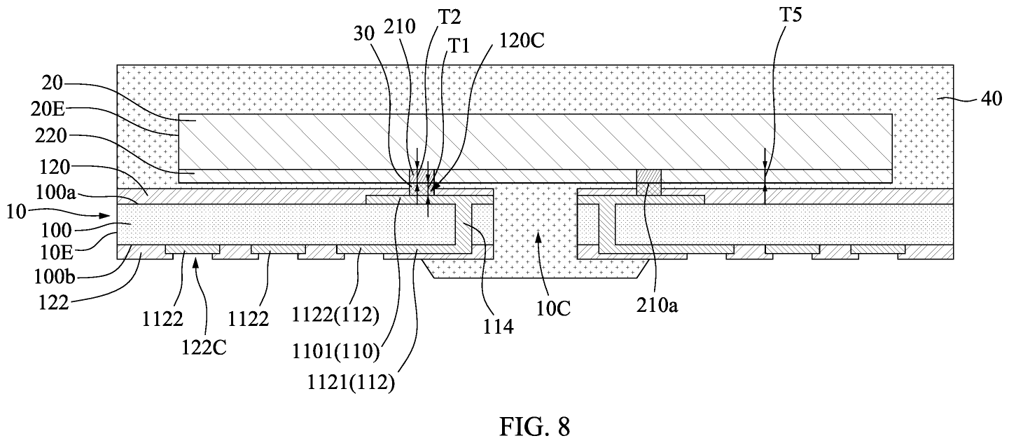

FIG. 8 illustrates one or more stages of a method of manufacturing a semiconductor structure, in accordance with some embodiments of the present disclosure.

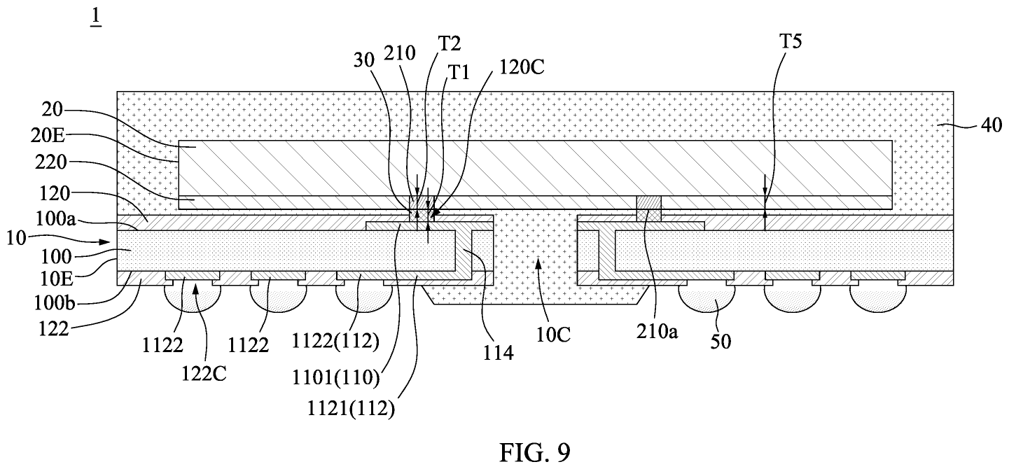

FIG. 9 illustrates one or more stages of a method of manufacturing a semiconductor structure, in accordance with some embodiments of the present disclosure.

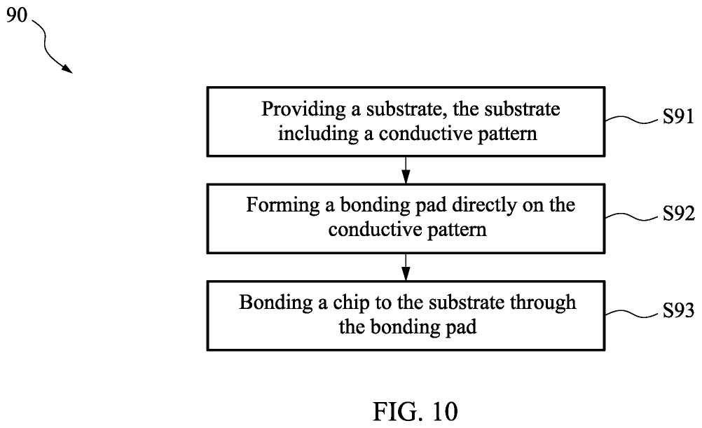

FIG. 10 is a flowchart illustrating a method of manufacturing a semiconductor structure, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1 is a cross-sectional view of a semiconductor structure 1, in accordance with some embodiments of the present disclosure. The semiconductor structure 1 includes a substrate 10, a chip 20, one or more bonding pads 30, an encapsulant 40, and conductors 50. In some embodiments, the semiconductor structure 1 may be a window ball grid array (WBGA) package.

The substrate 10 may be or include a semiconductor substrate, a metal plate, a package substrate, or the like. In some embodiments, the substrate 10 is or includes a printed circuit board (PCB).

In some embodiments, the substrate 10 includes a substrate body 100, one or more conductive patterns 110, one or more conductive patterns 112, one or more conductive vias 114, and insulating layers 120 and 122.

In some embodiments, the substrate body 100 is also referred to as a core layer. In some embodiments, the substrate body 100 is or includes a dielectric layer (e.g., bakelite). In some embodiments, the substrate body 100 is or includes a copper clay laminate (CCL) core, an epoxy base layer, or the like. The substrate body 100 may have a surface 100a and a surface 100b opposite to the surface 100a.

In some embodiments, the conductive pattern 110 is on the surface 100a of the substrate body 100. In some embodiments, the conductive pattern 110 includes one or more conductive lines 1101. In some embodiments, the conductive pattern 110 includes a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive pattern 110 includes copper.

In some embodiments, the conductive pattern 112 is on the surface 100b of the substrate body 100. In some embodiments, the conductive pattern 112 includes one or more conductive lines 1121 and one or more conductive pads 1122. The conductive line 1121 may be electrically connected to a corresponding conductive pad 1122. In some embodiments, the conductive pattern 112 includes a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive pattern 112 includes copper.

In some embodiments, the conductive via 114 penetrates the substrate body 100 between the surface 100a and the surface 100b. In some embodiments, the conductive via 114 penetrates the substrate body 100 to electrically connect the conductive pattern 110 and the conductive pattern 112. In some embodiments, the conductive via 114 penetrates the substrate body 100 to electrically connect the conductive line 1101 and the conductive line 1121. In some embodiments, the conductive via 114 electrically connects one of the conductive line 1101 to the corresponding conductive line 1121. In some embodiments, the conductive via 114 includes a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive via 114 includes copper.

In some embodiments, the insulating layer 120 is on the surface 100a of the substrate body 100. In some embodiments, the insulating layer 120 covers the conductive pattern 110. In some embodiments, the insulating layer 120 has one or more openings 120C. In some embodiments, a portion of the conductive pattern 110 is exposed by the opening 120C of the insulating layer 120. In some embodiments, the insulating layer 120 includes a polymeric material (e.g., polyimide or epoxy), CCL, BT resin, a solder resist film, or the like.

In some embodiments, the insulating layer 122 is on the surface 100b of the substrate body 100. In some embodiments, the insulating layer 122 has one or more openings 122C. In some embodiments, a portion of the conductive pattern 112 is exposed by the opening 122C of the insulating layer 122. In some embodiments, the conductive pads 1122 of the conductive pattern 112 are exposed by the openings 122C of the insulating layer 122. In some embodiments, the insulating layer 122 includes a polymeric material (e.g., polyimide or epoxy), CCL, BT resin, a solder resist film, or the like.

In some embodiments, the substrate 10 includes an opening 10C. The opening 10C is also referred to as a through hole or a window. In some embodiments, the opening 10C penetrates the substrate body 100, the conductive patterns 110 and 112, and the insulating layers 120 and 122.

The chip 20 may be disposed over the substrate 10. In some embodiments, one or more edges 20E of the chip 20 may be recessed with respect to one or more edges 10E of the substrate 10. In some embodiments, the chip 20 includes one or more conductive pads 210 and an insulating layer 220. In some embodiments, the chip 20 is or includes a memory device, e.g., a DRAM chip.

In some embodiments, the conductive pad 210 has a thickness T2 less than about 40 μm, about 35 μm, about 30 μm, about 25 μm, or about 20 μm. In some embodiments, the thickness T2 of the conductive pad 210 is from about 10 μm to about 20 μm. In some embodiments, the conductive pad 210 includes a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive pad 210 includes copper.

In some embodiments, the conductive pads 210 are embedded in the insulating layer 220. In some embodiments, top surfaces 220a (or bottom surfaces) of the conductive pads 210 are exposed by the insulating layer 220. In some embodiments, the insulating layer 220 has a thickness T5 less than about 40 μm, about 35 μm, about 30 μm, about 25 μm, or about 20 μm. In some embodiments, the thickness T of the insulating layer 220 is from about 10 μm to about 20 μm. In some embodiments, the thickness T of the insulating layer 220 is substantially the same as the thickness T2 of the conductive pad 210.

In some embodiments, the insulating layer 220 includes a polymeric material (e.g., polyimide or epoxy), CCL, BT resin, a solder resist film, or the like.

The bonding pad 30 (also referred to as “a bonding element”) may connect the substrate 10 to the chip 20. In some embodiments, the bonding pad 30 bonds the conductive pattern 110 of the substrate 10 to the conductive pad 210 of the chip 20. In some embodiments, the bonding pad 30 directly contacts the conductive pattern 110 of the substrate 10. In some embodiments, the bonding pad 30 is electrically connected to the conductive pattern 110 of the substrate 10. In some embodiments, the bonding pad 30 directly contacts the conductive pad 210 of the chip 20. In some embodiments, the bonding pad 30 is electrically connected to the conductive pad 210 of the chip 20. In some embodiments, the insulating layer 120 partially covers the bonding pad 30. In some embodiments, the bonding pad 30 is partially embedded in the insulating layer 120. In some embodiments, the bonding pad 30 is partially within the opening 120C of the insulating layer 120. In some embodiments, the bonding pad 30 includes a portion 310 exposed from the insulating layer 120 and directly contacting the conductive pad 210 of the chip 20. In some embodiments, a contact interface 116 between the bonding pad 30 and the conductive pattern 110 is embedded in the insulating layer 120.

In some embodiments, the bonding pad 30 includes a conductive material, such as tungsten, cobalt, zirconium, tantalum, titanium, aluminum, ruthenium, copper, tin, gold, metal carbides (e.g., tantalum carbide, titanium carbide, tantalum magnesium carbide), metal nitrides (e.g., titanium nitride), transition metal aluminides, or a combination thereof. In some embodiments, the bonding pad 30 includes a plated metal layer. In some embodiments, the bonding pad 30 includes a plated copper layer. In some embodiments, the bonding pad 30 is free of a soldering material (or a solder material). In some embodiments, the bonding pad 30 is free of tin, a tin alloy, or a tin-based alloy. In some embodiments, the bonding pad 30 is free of an intermetallic compound (IMC) formed of a metal and a solder material. In some embodiments, the bonding pad 30 includes a solder-free bonding structure. In some embodiments, the bonding pad 30 includes a solder-free metal bump. In some embodiments, the bonding pad 30 is monolithic or integrally formed. In some embodiments, the bonding pad 30 and the conductive pad 210 of the chip 20 include a same metal material. In some embodiments, the bonding pad 30, the conductive pad 210 of the chip 20, and the conductive pattern 110 of the substrate 10 include a same metal material. For example, the bonding pad 30, the conductive pad 210 of the chip 20, and the conductive pattern 110 of the substrate 10 may be or include copper.

In some embodiments, an aspect ratio of the bonding pad 30 is less than about 1, about 0.9, about 0.8, about 0.7, or about 0.6. In some embodiments, the bonding pad 30 has a thickness T1 less than about 40 μm, about 35 μm, about 30 μm, about 25 μm, or about 20 μm. In some embodiments, the thickness T1 of the bonding pad 30 is from about 10 μm to about 20 μm.

The encapsulant 40 may encapsulate the chip 20, the bonding pads 30, and a portion of the substrate 10. In some embodiments, the encapsulant 40 includes a molding compound including epoxy or any suitable materials. The encapsulant 40 may be referred to as a molding layer.

The conductors 50 may be disposed on the surface 100b of the substrate body 100. In some embodiments, portions of the conductors 50 are within the openings 122C of the insulating layer 122. In some embodiments, the conductors 50 are electrically connected to the conductive pattern 112. In some embodiments, the conductors 50 are electrically connected to the conductive pads 1122. The conductors 50 may include a conductive material with low resistivity, such as tin, lead, silver, copper, nickel, bismuth or an alloy thereof. In some embodiments, the conductors 50 include solder balls. In some embodiments, the conductors 50 include a ball grid array (BGA).

FIG. 2A shows one side of a semiconductor structure, in accordance with some embodiments of the present disclosure. In some embodiments, FIG. 2A shows a top side of the semiconductor structure 1. In some embodiments, FIG. 1 is a cross-section along the line A-A′ in FIG. 2A. Please be noted that some elements (e.g., the encapsulant 40, the conductors 50, and etc.) are omitted in FIG. 2A for clarity.

In some embodiments, the substrate 10 includes at least the conductive patterns 110, conductive vias 114, bonding pads 30, a conductive trace 110S, and a chip 20.

In some embodiments, the substrate 10 includes an opening 10C directly under the chip 20. In some embodiments, the opening 10C has edges 10C1, 10C2, 10C3, and 10C4. In some embodiments, the conductive trace 110S extends to the edge 10C1 of the opening 10C, and the conductive patterns 110 extend to the edge 10C2 and the edge 10C4 of the opening 10C. In some embodiments, the conductive trace 110S is electrically isolated from the conductive pattern 110 by the opening 10C. In some embodiments, the conductive trace 110S is a dummy trace serving no electrical connection function.

In some embodiments, the conductive pattern 110 includes a plurality of conductive lines 1101. In some embodiments, the conductive line 1101 is electrically connected to a corresponding conductive via 114. In some embodiments, each of the conductive lines 1101 is electrically connected to a corresponding conductive via 114. In some embodiments, the bonding pad 30 is disposed on and electrically connected to a corresponding conductive line 1101. In some embodiments, each of the bonding pads 30 is disposed on and electrically connected to a corresponding conductive line 1101. In some embodiments, as shown in FIG. 2A, the bonding pads 30 may be arranged to form a substantially straight line. In some other embodiments, the bonding pads 30 may be arranged on specific positions of the conductive lines 1101 that are not aligned in a straight line. The bonding pads 30 may be arranged according to the design rule of the corresponding conductive pads 210 of the chip 20.

FIG. 2B shows one side a semiconductor structure, in accordance with some embodiments of the present disclosure. In some embodiments, FIG. 2B shows a bottom side of the semiconductor structure 1. In some embodiments, FIG. 1 is a cross-section along the line A-A′ in FIG. 2B. Please be noted that some elements (e.g., the bonding pads 30, the encapsulant 40, the conductors 50, and etc.) are omitted in FIG. 2B for clarity.

In some embodiments, the conductive patterns 112 extend to the edge 10C2 and the edge 10C4 of the opening 10C of the substrate 10. In some embodiments, a portion of the chip 20 is exposed by the opening 10C as viewed from a bottom view perspective.

In some embodiments, the conductive pattern 112 includes a plurality of conductive lines 1121 and a plurality of conductive pads 1122. In some embodiments, the conductive line 1121 is electrically connected to a corresponding conductive via 114. In some embodiments, each of the conductive lines 1121 is electrically connected to a corresponding conductive via 114. In some embodiments, the conductive line 1121 is electrically connected to a corresponding conductive pad 1122. In some embodiments, each of the conductive lines 1121 is electrically connected to a corresponding conductive pad 1122.

Currently, a chip (e.g., a DRAM chip) may be bonded to a substrate by wire bond technique. However, high speed transmission (e.g., 5000 Mhz or higher) cannot be achieved by electrical transmission through bonding wires.

In some other cases, a chip may be bonded to a substrate by forming conductive pillars on conductive pads of the chip and then bonding the conductive pillars to conductive pads of the substrate through solder joints. However, the aforesaid process requires additional semiconductor processes of forming conductive pillars on the chip, which may increase the costs as well as the cycle time.

In contrast, according to some embodiments of the present disclosure, with the design of the bonding pad directly contacting the conductive pattern of the substrate to connect the substrate to the chip, the aforesaid additional semiconductor processes of forming conductive pillars on the chip can be omitted, and thus the costs as well as the cycle time can be reduced.

In addition, according to some embodiments of the present disclosure, with the design of the bonding pad being a solder-free bonding structure, since soldering materials having relatively low electrical conductivity are not present in the bonding pad, the electrical conductivity of the bonding pad can be improved, and thus the electrical performance of the semiconductor structure can be improved as well.

Moreover, according to some embodiments of the present disclosure, with the design of the bonding pad being a plated metal layer, the cost of a plating process is relatively low, and the bonding pad formed by the plating process can be provided with a relatively small thickness. Therefore, the transmission distance (or the transmission path) provided by the bonding pad is significantly shortened, which is advantageous to high speed transmission.

Furthermore, according to some embodiments of the present disclosure, with the design of the bonding pad being a plated metal layer, even if the plated metal layer may include a material having a relatively low electrical conductivity (e.g., a soldering material), the shortened transmission distance or path provided by the plated metal layer can compensate the reduction of electrical conductivity resulted from the soldering material, and thus the transmission speed can be relatively high compared to the cases where conductive pillars are used for bonding the chip to the substrate. Moreover, the plating process is performed on the substrate rather than on the chip, and thus additional semiconductor processes on the chip can be omitted, which is advantageous to reducing the manufacturing costs and the manufacturing time.

FIG. 3A to FIG. 9 illustrate various stages of a method of manufacturing a semiconductor structure 1, in accordance with some embodiments of the present disclosure.

FIG. 3A and FIG. 3B illustrate one or more stages of a method of manufacturing a semiconductor structure, in accordance with some embodiments of the present disclosure. In some embodiments, FIG. FIG. 3A is a top view of a portion of the structure illustrated in FIG. 3B.

Referring to FIG. 3A and FIG. 3B, a substrate 10 may be provided. In some embodiments, the substrate 10 includes a substrate body 100, one or more conductive patterns 110A, one or more conductive patterns 112, one or more conductive vias 114, insulating layers 120 and 122, and a conductive trace 110S1.

In some embodiments, providing the substrate 10 may include the following steps: providing a substrate body 100, forming the conductive pattern 110A on the substrate body 100, and forming an insulating layer 120 over the substrate body 100 and exposing a portion of the conductive pattern 110A. In some embodiments, providing the substrate 10 may further include the following steps: forming the conductive pattern 112 on the substrate body 100, and forming an insulating layer 122 over the substrate body 100 and exposing a portion of the conductive pattern 112. In some embodiments, the conductive pattern 110A includes a plurality of conductive lines 110A1, and the insulating layer 120 has one or more openings 120C exposing portions 110A11 of the conductive lines 110A1. In some embodiments, as shown in FIG. 3A, the insulating layer 120 has two openings 120C each exposes a plurality of portions 110A11 of the conductive lines 110A1.

In some embodiments, the conductive trace 110S1 connects the conductive pattern 110A to a voltage source 80. In some embodiments, the conductive trace 110S1 and the conductive pattern 110A may be formed by the same operation. In some embodiments, the conductive trace 110S1 extends between the openings 120C. In some embodiments, the conductive trace 110S1 connects or directly contacts the conductive lines 110A1 of the conductive pattern 110A. In some embodiments, the conductive trace 110S1 is over a portion 100C of the substrate 10.

In some embodiments, the substrate body 100 is also referred to as a core layer. In some embodiments, the substrate body 100 is or includes a dielectric layer (e.g., bakelite). In some embodiments, the substrate body 100 is or includes a copper clay laminate (CCL) core, an epoxy base layer, or the like.

In some embodiments, the conductive via 114 penetrates the substrate body 100 to electrically connect the conductive pattern 110A and the conductive pattern 112. In some embodiments, the conductive patterns 110A and 120, the conductive via 114, and the conductive trace 110S1 may independently include a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive patterns 110A and 120, the conductive via 114, and the conductive trace 110S1 include copper.

In some embodiments, the insulating layers 120 and 22 may independently include a polymeric material (e.g., polyimide or epoxy), CCL, BT resin, a solder resist film, or the like.

FIG. 4A and FIG. 4B illustrate one or more stages of a method

of manufacturing a semiconductor structure, in accordance with some embodiments of the present disclosure. In some embodiments, FIG. FIG. 4A is a top view of a portion of the structure illustrated in FIG. 4B.

Referring to FIG. 4A and FIG. 4B, one or more bonding pads 30 may be directly formed on one or more conductive patterns 110A.

In some embodiments, forming the bonding pads 30 may include the following steps: plating a metal layer (e.g., a copper layer) directly on one or more portions 110A11 of the conductive pattern 110A. In some embodiments, forming the bonding pads 30 may include the following steps: performing an electroplating process on one or more portions 110A11 of the conductive lines 110A1 exposed by the opening(s) 120C of the insulating layer 120. In some embodiments, the metal layer is plated directly on the portions 110A11 of the conductive pattern 110A exposed by the insulating layer 120. In some embodiments, the metal layer is plated directly on the portions 110A11 of the conductive pattern 110A exposed by the openings 120C of the insulating layer 120. In some embodiments, the conductive trace 110S1 serves to apply voltage to the conductive lines 110A1 from a voltage source 80.

In some embodiments, the as-formed bonding pad 30 (or the plated metal layer) may be protruded from a top surface of the insulating layer 120. In some embodiments, a top surface of the bonding pad 30 is higher than a top surface of the insulating layer 120. In some other embodiments, a top surface of the bonding pad 30 may be substantially coplanar with a top surface of the insulating layer 120. In some embodiments, as shown in FIG. 4A, a width of the as-formed bonding pad 30 (or the plated metal layer) is greater than a width of the conductive line 110A1. In some other embodiments, a width of the as-formed bonding pad 30 (or the plated metal layer) may be substantially equal to a width of the conductive line 110A1. In some embodiments, a sum of a thickness T3 of the conductive pattern 110A and the thickness T1 of the bonding pad 30 is greater than a thickness T4 of the insulating layer 120.

In some embodiments, the bonding pad 30 includes a conductive material, such as tungsten, cobalt, zirconium, tantalum, titanium, aluminum, ruthenium, copper, tin, gold, metal carbides (e.g., tantalum carbide, titanium carbide, tantalum magnesium carbide), metal nitrides (e.g., titanium nitride), transition metal aluminides, or a combination thereof.

FIG. 5A and FIG. 5B illustrate one or more stages of a method of manufacturing a semiconductor structure, in accordance with some embodiments of the present disclosure. In some embodiments, FIG. FIG. 5A is a top view of a portion of the structure illustrated in FIG. 5B.

Referring to FIG. 5A and FIG. 5B, a portion (e.g., the portion 100C) of the substrate 10 may be removed to form an opening 10C separating the conductive pattern 110 from the conductive trace 110S.

In some embodiments, a portion of the conductive trace 110S1

is removed along with the removal of the portion 100C of the substrate 10 to form the conductive trace 110S that is electrically separated or isolated from the conductive pattern 110. In some embodiments, the conductive trace 110S extends to the edge 10C1 of the opening 10C, and the conductive patterns 110 extend to the edge 10C2 and the edge 10C4 of the opening 10C. In some embodiments, the conductive trace 110S is electrically isolated from the conductive pattern 110 by the opening 10C.

FIG. 6A and FIG. 6B illustrate one or more stages of a method of manufacturing a semiconductor structure, in accordance with some embodiments of the present disclosure. In some embodiments, FIG. FIG. 6A is a top view of a portion of the structure illustrated in FIG. 6B.

Referring to FIG. 6A and FIG. 6B, a chip 20 may be bonded to the substrate 10 through the one or more bonding pads 30. In some embodiments, bonding the chip 20 to the substrate 10 through the bonding pads 30 may include the following step: directing the conductive pads 210 of the chip 20 to contact the bonding pads 30.

In some embodiments, the conductive trace 110S1 connects the conductive pattern 110A to a voltage source 80 prior to bonding the chip 20 to the substrate 10. In some embodiments, the conductive trace 110S is a dummy trace serving no electrical connection function.

In some embodiments, the chip 20 is or includes a memory device, e.g., a DRAM chip. In some embodiments, the conductive pad 210 includes a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive pad 210 includes copper.

FIG. 7 illustrates one or more stages of a method of manufacturing a semiconductor structure, in accordance with some embodiments of the present disclosure.

In some embodiments, bonding the chip 20 to the substrate 10 through the bonding pads 30 may include the following step: performing a bonding process P1 to bond the conductive pads 210 to the bonding pads 30. In some embodiments, the bonding process P1 is or includes a thermal compression process, an ultrasound heating process, or other suitable process. In some embodiments, the conductive pads 210 and the bonding pads 30 are copper, and the copper pads (i.e., the conductive pads 210 and the bonding pads 30) are bonded to each other to bond the chip 20 to the substrate 10.

FIG. 8 illustrates one or more stages of a method of manufacturing a semiconductor structure, in accordance with some embodiments of the present disclosure.

Referring to FIG. 8, an encapsulant 40 may be formed to encapsulate the chip 20, the bonding pads 30, and a portion of the substrate 10. In some embodiments, the encapsulant 40 includes a molding compound including epoxy or any suitable materials. The encapsulant 40 may be referred to as a molding layer.

FIG. 9 illustrates one or more stages of a method of manufacturing a semiconductor structure, in accordance with some embodiments of the present disclosure.

Referring to FIG. 9, conductors 50 may be disposed on the surface 100b of the substrate body 100. In some embodiments, portions of the conductors 50 are formed within the openings 122C of the insulating layer 122. In some embodiments, the conductors 50 are formed to electrically connect to the conductive pattern 112. In some embodiments, the conductors 50 are electrically connected to the conductive pads 1122. The conductors 50 may include a conductive material with low resistivity, such as tin, lead, silver, copper, nickel, bismuth or an alloy thereof. In some embodiments, the conductors 50 include solder balls. In some embodiments, the conductors 50 include a ball grid array (BGA).

FIG. 10 is a flowchart illustrating a method 90 of manufacturing a semiconductor device, in accordance with some embodiments of the present disclosure.

The method 90 begins with operation S91 in which a substrate is provided. In some embodiments, the substrate includes a conductive pattern.

The method 90 continues with operation S92 in which a bonding pad is directly formed on the conductive pattern.

The method 90 continues with operation S93 in which a chip is bonded to the substrate through the bonding pad.

The method 90 is merely an example, and is not intended to limit the present disclosure beyond what is explicitly recited in the claims. Additional operations can be provided before, during, or after each operations of the method 90, and some operations described can be replaced, eliminated, or moved around for additional embodiments of the method. In some embodiments, the method 90 can include further operations not depicted in FIG. 10. In some embodiments, the method 90 can include one or more operations depicted in FIG. 10.

One aspect of the present disclosure provides a semiconductor structure. The semiconductor structure includes a substrate having a conductive pattern. The semiconductor structure may also include a chip. The semiconductor structure may furthermore include a bonding pad connecting the substrate to the chip, where the bonding pad directly contacts the conductive pattern of the substrate.

Another aspect of the present disclosure provides a semiconductor structure. The semiconductor structure includes a substrate having a conductive pattern. The semiconductor structure may also include a chip having a conductive pad. The semiconductor structure may furthermore include a solder-free bonding structure bonding the conductive pattern of the substrate to the conductive pad of the chip.

Another aspect of the present disclosure provides a method of manufacturing a semiconductor structure. The method may include providing a substrate, the substrate having a conductive pattern. The method may also include forming a bonding pad directly on the conductive pattern. The method may furthermore include bonding a chip to the substrate through the bonding pad.

In the semiconductor structure, with the design of one or more bonding pads directly contacting one or more conductive patterns of a substrate to connect the substrate to a chip, additional semiconductor processes of forming conductive pillars on the chip can be omitted, and thus the costs as well as the cycle time can be reduced. In addition, with the design of the bonding pad being a plated metal layer, the cost of a plating process is relatively low, and the bonding pad formed by the plating process can be provided with a relatively small thickness. Therefore, the transmission distance (or the transmission path) provided by the bonding pad is significantly shortened, which is advantageous to high speed transmission.

Although the present disclosure and its advantages have been described in detail, it should be understood that various changes, substitutions and alterations can be made herein without departing from the spirit and scope of the disclosure as defined by the appended claims. For example, many of the processes discussed can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a semiconductor structure, comprising:
providing a substrate, the substrate comprising a conductive pattern;
forming a bonding pad directly on the conductive pattern; and
bonding a chip to the substrate through the bonding pad.

2. The method of claim 1, wherein providing the substrate further comprises:
providing a substrate body, wherein the conductive pattern is formed on the substrate body; and
forming an insulating layer over the substrate body and exposing a portion of the conductive pattern.

3. The method of claim 2, wherein forming the bonding pad comprises:
plating a metal layer directly on the portion of the conductive pattern exposed by the insulating layer.

4. The method of claim 3, wherein a sum of a thickness of the conductive pattern and a thickness of the metal layer is greater than a thickness of the insulating layer.

5. The method of claim 2, wherein the conductive pattern comprises a plurality of conductive lines, and the insulating layer has an opening exposing portions of the conductive lines.

6. The method of claim 5, further comprising:
forming a plurality of the bonding pads directly on the conductive lines, comprising:
performing an electroplating process on the portions of the conductive lines exposed by the opening of the insulating layer.

7. The method of claim 1, wherein the conductive pattern comprises copper, and forming the bonding pad comprises:
plating a copper layer directly on a portion of the conductive pattern.

8. The method of claim 1, wherein the substrate further comprises a conductive trace connecting the conductive pattern to a voltage source prior to bonding the chip to the substrate.

9. The method of claim 8, wherein forming the bonding pad comprises:
plating a metal layer directly on a portion of the conductive pattern; and
removing a portion of the substrate to form an opening separating the conductive pattern from the conductive trace.

10. The method of claim 1, wherein the chip comprises a conductive pad, and bonding the chip to the substrate comprises:
directing the conductive pad of the chip to contact the bonding pad; and
performing a thermal compression process to bond the conductive pad to the bonding pad.
